(19) United States
(12) Patent Application Publication
(10) Pub. No.: US 2016/0216607 A1
(43) Pub. Date: Jul. 28, 2016

(54) METHOD FOR FORMING RESIST PATTERN, AND COMPOSITION FOR FORMING RESIST PATTERN

(71) Applicant: NISSAN CHEMICAL INDUSTRIES, LTD., Tokyo (JP)

(72) Inventor: Tetsuo SATO, Funabashi-shi (JP)

(73) Assignee: NISSAN CHEMICAL INDUSTRIES, LTD., Tokyo (JP)

(21) Appl. No.: 14/915,516

(22) PCT Filed: Aug. 29, 2014
(86) PCT No.: PCT/JP2014/072800

§ 371 Date: Feb. 29, 2016

(30) Foreign Application Priority Data
Aug. 30, 2013 (JP) 2013-180388
Jan. 28, 2014 (JP) 2014-013491

(51) Int. Cl. G03F 7/028; G03F 7/20; G03F 7/32; G03F 7/16

(52) U.S. Cl. CPC G03F 7/028; G03F 7/16; G03F 7/20; G03F 7/32

(57) ABSTRACT

The invention provides a resist pattern formation method, employing a resist pattern forming composition which includes at least a polymerizable monomer that is liquid at room temperature, an organic gelling agent, and a photopolymerization initiator. The method includes a step of preparing the resist pattern forming composition; a step of applying, onto a substrate, the prepared resist pattern forming composition, to thereby form a coating film; a step of forming a gel with the organic gelling agent present in the coating film; and a step of patterning the coating film which has been gelled by the organic gelling agent.

### TECHNICAL FIELD

The present invention relates to a method for forming a resist pattern (hereinafter may be referred to as a “resist pattern formation method”) and to a composition for forming a resist pattern (hereinafter may be referred to as a “resist pattern forming composition”).

### BACKGROUND ART

Generally, a conventional mode of photolithography includes forming, on a substrate, a resist film formed of a resist pattern forming composition (hereinafter may be referred to simply as a “resist composition”), exposing the resist film selectively to radiation such as light or electron beam, and performing development, to thereby form a pattern of interest in the resist.

As the above resist material, there has been used a chemical amplification-type resist composition containing a base resin; an acid generator, which generates an acid by light exposure; and an organic solvent. For example, a positive-type chemical amplification-type resist contains a resin component which exhibits an alkali solubility increased by acid, and an acid-generating component which generates acid through exposure to light. Through application of the resist material onto a substrate and removal of the solvent via baking, a non-tacky resin film can be formed. When the thus-formed resin film is pattern-wise exposed to light, an acid is generated from the acid generator, whereby the exposed portion becomes alkali-soluble. The light-exposed portion is removed with an alkaline developer, to thereby obtain a resist pattern.

The required resist film thickness varies depending on the use thereof. For example, in production of semiconductor devices, the resist film formed from the resist composition generally has a thickness of about 100 to about 800 nm. In production of micro electro mechanical systems (MEMSs) and the like, the film thickness is greater. Conventionally, a thick resist film having a film thickness of, for example, 1 μm or more is used (see, for example, Patent Document 1).

In one conceivable and direct approach to form such a thick resist film, the film-forming component content of the resist composition (a solid content, when the film-forming component is solid) is increased. However, the viscosity of the resist composition increases with the solid content. As a result, problems occur such as impairment of in-plane uniformity in film thickness due to reduced leveling property and frequent occurrence of undesired lines in the formed film due to application of such a resist composition. Thus, there may be a need for providing, for example, a special coating apparatus in the production process thereof. In order to suppress such an increase in viscosity, a conceivable approach is heating the coating apparatus. However, the approach is not a fundamental resolution for the aforementioned problem, and the problem may still remain.

Another conceivable approach is application of a low-concentration coating composition a plurality of times to form a thick resist film. However, in such a case, productivity and yield may be impaired due to an increase in process steps.

Thus, there is demand for a resist composition which can have low viscosity and form a thick resist film. Regarding such resist composition material, there have been proposed a resist composition produced through a technique employing a low-viscosity solvent having a viscosity of 1.1 cP or lower at 20° C. (see, for example, Patent Document 2), a resist composition produced through a technique employing a mixed solvent containing propylene glycol monomethyl ether (see, for example, Patent Document 3), and a resist composition produced through a technique employing a polyfunctional thiol compound as a chain transfer agent (see, for example, Patent Document 4). However, as the use of the resist has been increased, there is further demand for a resist composition having higher film-forming component concentration and lower viscosity.

In order to lower the viscosity of the resist composition while maintaining a high resin concentration, there have been proposed a conceivable approach employing low-molecular-weight resin and that employing liquid resin. However, in the former approach, the film strength after removal of solvent decreases, thereby possibly impairing resist performance. In the latter approach, which employs liquid resin, a lower viscosity can be surely attained while elevating the film-forming component concentration. However, since the resist composition maintains flowability during exposure to UV light, the handling property is problematically impaired. Specifically, when a substrate onto which the resist composition has been applied is transferred to an UV exposure apparatus, the resist composition undesirably flows.

### PRIOR ART DOCUMENTS

### Patent Documents

### Patent Document 1: WO 2007/108253

Patent Document 2: Japanese Patent Application Laid-Open (kokai) No. 2008-70480
Patent Document 3: Japanese Patent Application Laid-Open (kokai) No. 2007-248727
Patent Document 4: Japanese kohyo (PCT) Patent Publication No. 2010-523810

### SUMMARY OF THE INVENTION

### Problems to be Solved by the Invention

The present invention has been accomplished under such circumstances. Thus, an object of the present invention is to provide a resist pattern formation method employing a resist composition which has high film-forming component concentration but exhibits low viscosity, which attains high in-plane uniformity in thickness during application thereof, and which has excellent handling property. Another object is to provide such a resist pattern forming composition.

### Means for Solving the Problems

In one mode of the present invention for attaining the aforementioned objects, there is provided a resist pattern formation method, employing a resist pattern forming composition which comprises at least a polymerizable monomer that is liquid at room temperature, an organic gelling agent, and a photopolymerization initiator,

characterized in that the method comprises:

a step of preparing the resist pattern forming composition;

a step of applying, onto a substrate, the prepared resist pattern forming composition, to thereby form a coating film;

a step of forming a gel with the organic gelling agent present in the coating film; and

a step of patterning the coating film which has been gelled by the organic gelling agent.

In the gelling step, the organic gelling agent is preferably heated at 40 to 160° C.

Also, the organic gelling agent is preferably in a granular form.

Also, the resist pattern forming composition preferably contains an organic solvent for dissolving the organic gelling agent.

Also, the resist pattern forming composition preferably contains an emulsifier.

In the patterning step, preferably, the coating film formed on the substrate is cured via exposure to UV light, and then the uncured portion of the coating film on the substrate is removed with an alkaline developer.

In another mode of the present invention for attaining the aforementioned objects, there is provided a resist pattern forming composition, characterized in that the composition comprises at least a polymerizable monomer, an organic gelling agent, and a photopolymerization initiator, and the polymerizable monomer is liquid at room temperature.

In the composition, the organic gelling agent is preferably at least one of dextrin palmitate and 12-hydroxystearic acid.

### Effects of the Invention

According to the resist pattern formation method of the present invention, the resist composition contains a polymerizable monomer that is liquid at room temperature. Thus, a thick coating film can be formed on the substrate. In addition, since the composition contains an organic gelling agent, flow of the coating film can be suppressed. As a result, a thick coating film having excellent in-plane uniformity in thickness can be maintained during conveyance of the substrate even after application of the resist composition.

The resist pattern forming composition of the present invention contains a polymerizable monomer that is liquid at room temperature and an organic gelling agent. Thus, for the same reason, a thick coating film having excellent in-plane uniformity in thickness can be provided.

### BRIEF DESCRIPTION OF THE DRAWINGS

FIG. 1 A microscopic image of a substrate on which circular pattern has been formed.

### MODES FOR CARRYING OUT THE INVENTION

### Resist Composition

Hereinafter, the present invention will next be described in detail.

The resist composition of the present invention contains at least a polymerizable monomer, a photopolymerization initiator, and an organic gelling agent, wherein the polymerizable monomer is liquid at room temperature. Thus, the resist composition of the present invention exhibits low viscosity, while the composition has high film-forming component concentration.

By use of the resist composition of the present invention, a coating film having a relatively large thickness can be formed on the substrate. Furthermore, the coating film is subjected to gelation, to thereby express the gelation performance of the organic gelling agent. As a result, flow of the coating film can be suppressed through gelling the coating film, whereby excellent handling property can be attained.

As used herein, the term “room temperature” refers to 25° C. The term “film-forming component” refers to a component of the resist composition which component will form the resist film obtained from the composition. The “film-forming component concentration” generally refers to a weight-basis total amount of the organic gelling agent, the photopolymerization initiator, and the polymerizable monomer, with respect to the entire amount of the resist composition.

### <Polymerizable Monomer>

As used herein, the “polymerizable monomer” refers to an ethylenic unsaturated monomer; i.e., a compound having at least one ethylenic unsaturated double bond.

Such a polymerizable monomer is preferably liquid with low viscosity at room temperature.

Notably, the “low viscosity at room temperature” in the present invention refers to a viscosity of 100 cP or lower at 25° C.

In one preferred embodiment of the present invention, the polymerizable monomer is liquid with low viscosity at room temperature. Thus, even when the amount of the polymerizable monomer forming the substantially entirety of the film-forming component is increased, an excessive increase in viscosity of the resist composition can be prevented, whereby the viscosity of the resist composition can be lowered at high reproducibility.

The polymerizable monomer may be selected from among a mono-functional (meth)acrylate, a bi-functional (meth)acrylate, a (meth)acrylate having 3 or more functionalities, etc., in consideration of use of the resist. Among them, a mono-functional (meth)acrylate is effective from the viewpoints of low viscosity and suitable adhesion. Particularly, a C≧6 aliphatic or alicyclic alkyl (meth)acrylate is preferred.

Examples of the C≧6 aliphatic or alicyclic alkyl (meth)acrylate include hexyl (meth)acrylate, 2-ethylhexyl (meth)acrylate, heptyl (meth)acrylate, octyl (meth)acrylate, isooctyl (meth)acrylate, nonyl (meth)acrylate, isononyl (meth)acrylate, decyl (meth)acrylate, isodecyl (meth)acrylate, dodecyl (meth)acrylate, stearyl (meth)acrylate, isostearyl (meth)acrylate, lauryl (meth)acrylate, cyclohexyl (meth)acrylate, isobornyl (meth)acrylate, isoamyl (meth)acrylate, dicyclopentenyl (meth)acrylate, and tricyclodecanyl (meth)acrylate. Of these, isodecyl (meth)acrylate, lauryl (meth)acrylate, cyclohexyl (meth)acrylate, isostearyl (meth)acrylate, and 2-ethylhexyl (meth)acrylate are suitably used.

Examples of mono-functional (meth)acrylates other than the C≧6 aliphatic or alicyclic alkyl (meth)acrylate include methyl (meth)acrylate, ethyl (meth)acrylate, phenoxyethyl (meth)acrylate, glycerin mono(meth)acrylate, glycidyl (meth)acrylate, dicyclopentenyl (meth)acrylate, n-butyl (meth)acrylate, benzyl (meth)acrylate, phenol-ethylene oxide adduct (n=2) (meth)acrylate, nonylphenol-propylene oxide adduct (n=2.5) (meth)acrylate, 2-(meth)acryloyloxyethyl acid phosphate, furfuryl (meth)acrylate, carbitol (meth)acrylate, benzyl (meth)acrylate, butoxyethyl (meth)acrylate, allyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-hydroxy-3-phenoxypropyl (meth)acrylate, and 3-chloro-2-hydroxypropyl (meth)acrylate.

Among them, an acrylate having a molecular weight of about 100 to about 300 is preferably used as the polymerizable monomer. By use of such an acrylate, the viscosity of the resist composition can be readily lowered, while the film-forming component concentration is elevated.

Examples of the bi-functional (meth)acrylate include ethylene glycol di(meth)acrylate, diethylene glycol di(meth)acrylate, tetraethylene glycol di(meth)acrylate, polyethylene glycol di(meth)acrylate, propylene glycol di(meth)acrylate, dipropylene glycol di(meth)acrylate, polypropylene glycol di(meth)acrylate, butylene glycol di(meth)acrylate, neopentyl glycol di(meth)acrylate, ethylene oxide-modified bisphenol A di(meth)acrylate, propylene oxide-modified bisphenol A di(meth)acrylate, 1,6-hexanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, diglycidyl phthalate di(meth)acrylate, and hydroxypivalic acid-modified neopentyl glycol di(meth)acrylate.

Examples of the (meth)acrylate having 3 or more functionalities include trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, tri(meth)acryloyloxyethoxytrimethylolpropane, and glycerin polyglycidyl ether poly(meth)acrylate.

These polymerizable monomers may be used singly or in combination of two or more species.

In addition to such polymerizable monomers, a high-viscosity polymerizable monomer liquid having a viscosity higher than about 100 cP, or a polymerizable monomer which is solid at room temperature may also be used in combination, so long as the viscosity of the polymerizable monomer and that of the resist composition is not excessively elevated (for example, the application technique and use of the resist composition are not excessively restricted).

### <Organic Gelling Agent>

In the present invention, no particular limitation is imposed on the organic gelling agent, so long as the agent can form a gel of the resist composition at room temperature. Specifically, the gelling agent essentially provides such a thermally reversible property that the solid gel transforms to flowable liquid (sol) through heating, and the sol transforms into a solid (gel) through cooling. When an organic gelling agent having high compatibility with the polymerizable monomer is used, the agent can be suitably mixed with the monomer.

Notably, as used herein, the term “gelling” refers to such a process that the flowable body loses flowability to form a solid which does not collapse by its own weight.

An example of such an organic gelling agent is an oil gelling agent (i.e., an oily gelling agent). Specific examples include an amino acid derivative, a long-chain fatty acid, a long-chain fatty acid polyvalent metal salt, a saccharide derivative, and a wax. Of these, an amino acid derivative and a long-chain fatty acid are preferred, by virtue of suitable gelling property.

Specific examples of the amino acid derivative include (preferably C2 to C15) amino acid derivatives in which an amino group is acylated or a carboxyl group is esterified or amidated) such as di(cholesteryl/behenyl/octyldodecyl) N-lauroyl-L-glutamate, di(cholesteryl/octyldodecyl) N-lauroyl-L-glutamate, di(phytosteryl/behenyl/octyldodecyl) N-lauroyl-L-glutamate, di(phytosteryl/octyldodecyl) N-lauroyl-L-glutamate, N-lauroyl-L-glutamic acid dibutylamide, and N-ethylhexanoyl-L-glutamic acid dibutylamide. Of these, N-lauroyl-L-glutamic acid dibutylamide and N-ethylhexanoyl-L-glutamic acid dibutylamide are particularly preferred.

Specific examples of the long-chain fatty acid include C8 to C24 saturated or unsaturated long-chain fatty acid and an analog thereof (e.g., 12-hydroxystearic acid). Specific examples of the saturated fatty acid include octanoic acid, 2-ethylhexanoic acid, decanoic acid, lauric acid, myristic acid, stearic acid, palmitic acid, arachidic acid, and behenic acid. Specific examples of the unsaturated fatty acid include palmitoleic acid, oleic acid, vaccenic acid, linoleic acid, linolenic acid, arachidonic acid, eicosadienoic acid, and erucic acid.

Specific examples of the long-chain fatty acid metal salt include metal salts of the same long-chain fatty acid. In the case of a C18-chain saturated fatty acid, examples include aluminum stearate, magnesium stearate, manganese stearate, iron stearate, cobalt stearate, calcium stearate, and lead stearate.

Specific examples of the saccharide derivative include dextrin fatty acid esters such as dextrin laurate, dextrin myristate, dextrin palmitate, dextrin margarate, dextrin stearate, dextrin arachidate, dextrin lignocerate, dextrin cerotate, dextrin 2-ethylhexanoate palmitate and dextrin palmitate stearate; sucrose fatty acid esters such as sucrose palmitate, sucrose stearate, and sucrose acetate/stratare; oligofructose fatty acid esters such as oligofructose stearate and oligofructose 2-ethylhexanoate; and benzylidene sorbitol derivatives such as monobenzylidene sorbitol and dibenzylidene sorbitol.

Among them, long-chain fatty acids such as 12-hydroxystearic acid (melting point: 78° C.) and saccharide derivatives such as dextrin palmitate (melting temperature: 85 to 90° C.), which are compounds melting at 70 to 100° C., are preferred, from the viewpoints of gelling property and the like.

Also, a long-chain fatty acid such as 12-hydroxystearic acid is preferred, since such an acid loses gelling property by reaction with an alkaline developer, an unexposed gel portion returns to a low-viscosity resin composition, whereby development can be facilitated.

Notably, these organic gelling agents may be used singly or in combination of two or more species.

The organic gelling agent content of the resist composition of the present invention is preferably 0.1 to 30 parts by mass, with respect to 100 parts by mass of the resin composition, more preferably 3 to 10 parts by mass. When the organic gelling agent content falls within the above range, the coatability of the composition can be enhanced at high reproducibility, while both intrinsic properties of the resist composition, and adhesion thereof to a substrate are maintained.

Gelling performance may be realized through, for example, the following technique.

Specifically, when a granular-form organic gelling agent; i.e., a solid organic gelling agent, is used, the organic gelling agent is melted by heat in the gelling step before exposure to UV light, whereby the gelling agent is uniformly incorporated into the resist composition. When the temperature of the composition lowers to room temperature, a gel of the composition is formed.

The granular-form organic gelling agent also serves as a filler. Thus, even when an organic gelling agent of interest is used with the liquid-form polymerizable monomer, an excessive increase in viscosity of the composition is prevented, and also, a high concentration of film-forming component can be attained. As a result, for example, a coating film having a considerable thickness can be formed on a substrate, and the thick coating film can be transformed into a gel on the substrate. Thus, during transfer of the substrate to a UV exposure apparatus, flow of the resist composition from the substrate can be prevented, to thereby enhance a resist handing property.

In the case where a solution of the organic gelling agent dissolved in an organic solvent is used, the organic solvent evaporates in the gelling step, and the relative organic gelling agent concentration increases. From another aspect, the organic solvent which impedes the interaction of the organic gelling agent is removed, whereby the resist composition can be converted to a gel around room temperature.

The organic solvent used in this case is required to have ability to dissolve the organic gelling agent therein, and to serve as a gelling-suppressing agent for preventing cohesion of the organic gelling agent via hydrogen bond. When the organic solvent suppresses the gelling by the action of the organic gelling agent, a rise in viscosity of the resist composition due to gelation can be prevented, before application of the resist composition onto a substrate.

An example of the organic solvent serving as the gelling-suppressing agent is a C≦5 lower alcohol. Specific examples include ethanol, methanol, butanol, and isopropanol. Alternatively, ethyl acetate, methyl ethyl ketone, dimethylacetamide, 1-methoxy-2-proanol (PGME), or the like may be used as an organic solvent which can serve as the gelling-suppressing agent.

In the present invention, the organic solvent must be removed from the resist composition through heating in the gelling treatment. Therefore, the organic solvent serving as the gelling-suppressing agent is required to have a low boiling temperature. Particularly, all the above exemplified organic solvents, having low boiling temperature, can be uniformly mixed with the polymerizable monomer. Thus, these solvents are suitable for the organic solvent serving as the gelling-suppressing agent.

### <Photopolymerization Initiator (Radiation Radical Polymerization Initiator)>

Examples of the radiation radical polymerization initiator employed in the present invention include α-diketones such as diacetyl; acyloins such as bezoin; acyloin ethers such as benzoin methyl ether, benzoin ethyl ether, and benzoin isopropyl ether; benzophenones such as thioxanthone, 2,4-diethylthioxanthone, thioxanthone-4-sulfonic acid, benzophenone, 4,4′-bis(dimethylamino)benzophenone, and 4,4′-bis(diethylamino)benzophenone; acetophenones such as acetophenone, p-dimethylaminoacetophenone, α,α-dimethoxy-α-acetoxyacetophenone, α,α-dimethoxy-α-phenylacetophenone, p-methoxyacetophenone, 1-[2-methyl-4-methylthiophenyl]-2-morpholino-1-propanone, α,α-dimethoxy-α-morpholino-methylthiophenylacetophenone, and 2-benzyl-2-dimethylamino-1-(4-morpholinophenyl)butan-1-one; quinones such as anthraquinone, and 1,4-naphthoquinone; halogen compounds such as phenacyl chloride, tribromomethyl phenyl sulfone, and tris(trichloromethyl)-s-triazine; bisimidazoles such as [1,2′-bisimidazole]-3,3′,4,4′-tetraphenyl and [1,2′-bisimidazole]-1,2′-dichlorophenyl-3,3′,4,4′-tetraphenyl; peroxides such as di-tert-butyl peroxide; and acylphosphine oxides such as 2,4,6-trimethylbenzoyl(diphenyl)phosphine oxide.

Examples of commercial radiation radical polymerization initiators include Irgacur 184, 369, 379EG, 651, 500, 907, CGI369, and CG24-61, Lucirin LR8728, Lucirin TPO, Darocur 1116 and 1173 (products of BASF), and Ubecryl P36 (product of UCB).

Among them, preferred are acetophenones such as 1-[2-methyl-4-methylthiophenyl]-2-morpholino-1-propanone, 2-benzyl-2-dimethylamino-1-(4-morpholinophenyl)butan-1-one, and α,α-dimethoxy-α-phenylacetophenone; phenacyl chloride, tribromomethyl phenyl sulfone, 2,4,6-trimethylbenzoyl(diphenyl)phosphine oxide, a combination of 1,2′-bisimidazoles, 4,4′-diethylaminobenzophenone, and mercaptobenzothiazole, Lucirin TPO (tradename), Irgacur 651 (tradename), and Irgacur 369 (tradename).

The radiation radical polymerization initiator content is preferably 0.1 to 50 parts by mass, with respect to 100 parts by mass of the polymerizable monomer, more preferably 1 to 30 parts by mass, particularly preferably 2 to 30 parts by mass.

When the radiation radical polymerization initiator content is lower than the lower limit of the above range, the resist composition readily undergoes deactivation of radicals by oxygen (i.e., drop in sensitivity), whereas when the initiator content is higher than the upper limit of the above range, compatibility and storage stability tend to be impaired.

These radiation radical polymerization initiators may be used singly or in combination of two or more species.

If required, the resist composition of the present invention may further contain a hydrogen-donating compound such as mercaptobenzothiazole and mercaptobenzoxazole, or a radiation sensitizer, in addition to the radiation radical polymerization initiator.

### <Emulsifier>

The resist composition of the present invention may further contain an emulsifier, in order to enhance compatibility of the polymerizable monomer to the organic gelling agent.

By use of an emulsifier, when a granular-form organic gelling agent is used, the organic gelling agent can be readily and uniformly dispersed in the polymerizable monomer, whereas when a solution of the organic gelling agent dissolved in the organic solvent is used, separation of the organic gelling agent from the polymerizable monomer can be effectively prevented.

Examples of the emulsifier which may be used in the invention include modified silicone oils such as KF-640, KF-6012, and KF-6017 (products of Shin-Etsu Silicone); and polyoxyethylene alkyl ethers such as Pegnol O-20, 16A, and L-9A (products of Toho Chemical Industry Co., Ltd).

The performance of emulsifier is evaluated by hydrophile-lipophile balance (HLB), wherein HLB of a substance having no hydrophilic group is defined as 0, and HLB of a substance having no lipophilic group but only a hydrophilic group is defined as 20. That is, the emulsifier has an HLB of 0 to 20. A suitable HLB value is appropriately chosen in accordance with the type of the resist composition.

Notably, a compound serving as an emulsifier generally has the same structure as that of a compound serving as a surfactant. Therefore, the emulsifier and the surfactant may have virtually the same definition. However, the aforementioned enhancement in compatibility cannot be attained by use of a conventional surfactant. Thus, as defined in the present invention, the emulsifier differs from the surfactant. By use of such an emulsifier, uniformity of the resist film after curing can be further enhanced.

Although the mechanism of the above effect has not been completely elucidated, the transparency of the cured product is enhanced. Thus, a conceivable mechanism is as follows. Specifically, growth of the structure of the organic gelling agent in the cured product is impeded, and the organic gelling agent structure remains in relatively small entities. There has been known a compound having such an effect as a gelling inhibitor. However, it has not been reported that the emulsifier can be used as the gelling inhibitor.

The emulsifier content is preferably 5 parts by mass or less, with respect to 100 parts by mass of the polymerizable monomer.

### <Other Components>

In addition to the polymerizable monomer, the organic gelling agent, the emulsifier, and the radiation radical polymerization initiator, the resist composition of the present invention may further contains, other components such as additives (e.g., a surfactant) and a solvent in accordance with needs.

Furthermore, as described above, the resist composition of the present invention may contain a high-viscosity monomer such as a urethane acrylate or a high-molecular-weight component, so long as the viscosity of the resist composition does not increase. Notably, a preferred viscosity of the resist composition is determined in accordance with use and other factors involved in the resist composition.

### <Surfactants>

The resist composition of the present invention may further contain a surfactant, so as to enhance coatability, defoaming performance, leveling property, etc.

Examples of such surfactants include commercial fluorine-containing surfactants such as BM-1000 and BM-1100 (products of BM Chemie), Megafac F142D, F172, F173, and F183 (products of DIC Coproration), Flourad FC-135, FC-170C, FC-430, and FC-431 (products of Sumitomo 3M), Surflon S-112, S-113, S-131, S-141, and S-145 (products of Asahi Glass), and SH-28PA, -190, -193, SZ-6032, and SF-8428 (products of Dow Corning Silicone Toray).

The surfactant content is preferably 5 parts by mass or less, with respect to 100 parts by mass of the resist composition.

### <Solvent>

In the present invention, a known solvent for dissolving the polymerizable monomer to form a uniform solution may be used, in addition to the aforementioned organic solvent serving as the gelling-suppressing agent; i.e., an organic solvent for dissolving the organic gelling agent. So long as the objects of the present invention are not impaired, the resist composition may contain such a conventional solvent.

From the viewpoints of solubility, reactivity to each component, and ease of forming coating film, the general solvent may be contained in the resist composition. Examples of preferred solvents include polyol alkyl ethers such as ethylene glycol monoethyl ether, diethylene glycol monomethyl ether, and 1-methoxy-2-proanol (PGME); polyol alkyl ether acetates such as ethylene glycol ethyl ether acetate and propylene glycol monomethyl ether acetate; esters such as ethyl 3-ethoxypropionate, methyl 3-methoxypropionate, ethyl 2-hydroxypropionate, and ethyl lactate; and ketones such as diacetone alcohol.

Notably, the amount of such a conventional solvent is appropriately predetermined in accordance with use of the composition, application method, etc.

The aforementioned resist composition of the present invention can be suitably used as a negative-type resist composition, since a thin film formed by curing the coating film of the composition does not dissolve in a developer such as an alkaline solution and exhibits excellent barrier property to fluoric acid or the like.

### <Resist Pattern Formation Method (Method for Producing Various Substrates Having a Resist Pattern)>

The resist pattern formation method of the present invention includes a step of preparing the aforementioned resist pattern forming composition, a step of applying, onto a substrate, the prepared resist composition, to thereby form a coating film; a step of forming a gel with the organic gelling agent present in the coating film; and a step of patterning the coating film which has been gelled by the organic gelling agent. Each step of the resist pattern formation method of the present invention will next be described in detail.

### (1) Preparation of Resist Composition

As described above, the resist composition contains at least a polymerizable monomer, an organic gelling agent, and a photopolymerization initiator, wherein the polymerizable monomer is liquid at room temperature with low viscosity. The composition can be prepared by mixing these components.

The organic gelling agent in a granular form (i.e., solid) may be mixed with the polymerizable monomer and the photopolymerization initiator. In an alternatively way, the organic gelling agent is dissolved in an organic solvent serving as a gelling-suppressing agent, and the solution is mixed with the polymerizable monomer and the photopolymerization initiator.

If required, the resist composition may be prepared by mixing the above essential components with an emulsifier and an additional component.

No particular limitation is imposed on the method and timing of mixing an emulsifier, so long as the aforementioned function of the emulsifier is not impaired. For example, the following steps may be performed.

Specifically, the polymerizable monomer, the organic gelling agent, the photopolymerization initiator, and other essential components are placed in a glass-made sample bottle or the like, and an emulsifier and an additional component are added to the sample bottle. The bottle is closed with a cap, and the contents are stirred by shaking, to thereby prepare a resist composition.

### (2) Formation of Coating Film

Examples of the method of applying the resist composition onto the substrate, which may be employed in the present invention, spin coating, slit coating, roller coating, screen printing, and applicator coating.

Particularly when slit coating is employed, the resist composition must have a relatively low viscosity. The resist composition of the present invention contains a liquid polymerizable monomer, and has high film-forming component concentration and low viscosity. Therefore, the resist composition of the invention can be applied onto the substrate through slit coating.

No particular limitation is imposed on the shape, structure, size, etc. of the substrate, so long as the gist of the present invention is not changed. No particular limitation is also imposed on the material of the substrate, and a substrate made of an inorganic material such as soda glass may be employed.

### (3) Gelling (Gel Formation)

Conditions under which the coating film of the resist composition of the present invention is gelled are varied in accordance with the species and amount of a component contained in the composition, the thickness of the coating film, and other factors. Generally, the coating film is heated at 40 to 160° C., preferably 60 to 120° C., for about 3 to about 15 minutes. When the heating temperature and heating time are excessively low and short, adhesion of the coating film onto the substrate during development is impaired, whereas when the heating temperature and heating time are excessively high and long, resolution of the patterning may be lowered by excessive heating.

In an alternative mode of the gelling step, the organic gelling agent is heated in the aforementioned manner, and the resist composition is intentionally cooled to room temperature or thereabout. Through this alternative mode, the rate of lowering the temperature of the resist composition can be accelerated, to thereby increase the gel-formation rate.

The thickness of the coating film of the resist composition of the present invention is preferably 1 to 100 μm, more preferably 5 to 30 μm. The required thickness of the resist film varies depending on the use of the resist film. However, the resist composition of the present invention can be suitably formed into thin film and thick film.

### (4) Patterning

### (4-1) Exposure to Radiation

A photomask having a pattern of interest was applied onto the thus-gelled coating film, and the coating film was exposed to a radiation (e.g., an UV ray or visible light of a wavelength of 300 to 500 nm), whereby the light-exposed portion can be cured.

As used herein, the term “radiation” encompasses UV rays, visible light, deep UV light, X ray, and electron beam. Examples of the light source which may be employed in the invention include a low-pressure mercury lamp, a high-pressure mercury lamp, an ultra-high-pressure mercury lamp, a metal halide lamp, and an argon gas laser.

The dose of radiation varies depending on the type and amount of a component included in the composition, the thickness of the coating film, and the like. In the case where a high-pressure mercury lamp is employed, the dose is 100 to 1,500 mJ/cm².

Thus, through curing the coating film, the cured coating film does not dissolve in a developer such as an alkaline developer solution, and exhibits excellent barrier property against fluoric acid or the like.

### (4-2) Development

In one procedure of the development after exposure to radiation, an unrequired, non-light-exposed portion of the film is dissolved by use of an aqueous alkaline solution or an organic solvent serving as a developer, to thereby remove the portion and exclusively leaving the light-exposed portion, whereby a target pattern of the cured film is obtained. Examples of the alkaline developer include aqueous solution of alkalines such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene, and 1,5-diazabicyclo[4.3.0]-5-nonane.

The aforementioned aqueous alkaline solution may further contain an appropriate amount of a water soluble organic solvent such as methanol or ethanol, or a surfactant. Such an aqueous solution may also be employed as a developer.

No particular limitation is imposed on the organic solvent developer, so long as the solvent can suitably dissolve the resist composition after formation of gel. Examples of the organic solvent which may be used in the invention include aromatic compounds such as toluene and xylene; aliphatic compounds such as n-hexane, cyclohexane, and isoparaffin; ether compounds such as tetrahydrofuran; ketones such as methyl ethyl ketone and cyclohexanone; esters such as acetate esters; and halogen-containing compounds such as 1,1,1-trichloroethane. In order to regulate the development speed, the developer may further contain an appropriate amount of a solvent (e.g., ethanol and isopropanol), which does not dissolve the resist composition, after gelation.

The development time, which varies in accordance with varies the type and amount of a component included in the composition, the thickness of the coating film, and the like, is generally 30 to 1,000 seconds. The development technique may be any of dipping, the paddle method, spraying, and showering. In one possible mode, the cured product is washed by means of a flow of water for 30 to 90 seconds, and then dried under air flow created by means of spin drying or an air gun, or drying by means of a hot plate or an oven.

Thus, in the present invention, the resist pattern forming composition formed on the substrate is cured by exposure to UV light ((4-1) as mentioned above), and then, the unexposed portion of the resist composition formed on the substrate is removed by use of an alkaline developer ((4-2) as mentioned above), and patterning is performed. Alternatively, the below-mentioned post treatment may be further performed.

### (4-3) Post Treatment

The coating film obtained from the resist composition of the present invention can be sufficiently cured only by the aforementioned radiation. However, additional exposure to radiation (hereinafter referred to as “post exposure”) or heating may be employed for further curing.

Post exposure may be performed in the same manner as employed in the aforementioned exposure to radiation. No particular limitation is imposed on the radiation dose, but the dose is preferably 100 to 2,000 mJ/cm², when a high-pressure mercury lamp is used. In the case where heating is employed, the coating film is heated at a specific temperature (e.g., 60 to 150° C.) for a specific time (e.g., 5 to 30 minutes (hot plate) or 5 to 60 minutes (oven)) by means of a heating apparatus (e.g., a hot plate or an oven). Through such a post exposure process, a cured film having a pattern of interest and more suitable characteristics can be obtained.

Through the aforementioned procedure, a resist pattern can be formed.

Next will be described an embodiment of forming a pattern on a glass substrate by use of such a resist pattern.

Firstly, a pattern of interest is formed from the cured film on a glass substrate through the aforementioned method. Then, the substrate provided with the cured film is etched.

Etching may be performed through a known method such as wet etching, dry etching (i.e., chemical etching under reduced pressure), or a combination thereof.

Examples of the etchant employed in wet etching include hydrofluoric acid, hydrofluoric acid-ammonium fluoride, and a mixed acid of hydrofluoric acid with another acid (e.g., hydrochloric acid, sulfuric acid, or phosphoric acid). Dry etching may be performed by use of CF gas or the like.

Subsequently, the cured film is removed from the substrate. Examples of the component of the remover used herein include an inorganic alkaline component such as sodium hydroxide or potassium hydroxide, and an organic alkali component such as a tertiary amine (e.g., trimethanolamine, triethanolamine, or dimethylaniline) or a quaternary ammonium (e.g., tetramethylammonium hydroxide or tetraethylammonium hydroxide). Examples of the solvent of the remover include water, dimethyl sulfoxide, N-methylpyrrolidone, and a mixture thereof. In use, the component is dissolved in the solvent. Alternatively, an aromatic or aliphatic solvent such as toluene, xylene, or limonene may be used as a remover. In this case, the resist film swells by the solvent, and the swelled film can be removed from the substrate.

By use of the aforementioned remover, the cured film may be removed through a technique such as spraying, showering, or a paddle method. Yet alternatively, the resist film may be peeled from the substrate without using a remover.

### EXAMPLES

Polymerizable monomers having a viscosity shown in Table 1 and photopolymerization initiators shown in Table 1 were mixed at proportions shown in Table 1, to thereby prepare resin compositions [1] and [2]. Notably, when UV-36351D80 or the like includes an additional polymerizable monomer (e.g., SR395), the total monomer content was adjusted to the corresponding value shown in Table 1.

TABLE 1

| | Polymerizable monomers (viscosity) | | | | | | | | | |
|---|---|---|---|---|---|---|---|---|---|---|
| | UV- | | | | | | | | | |
| | 3635ID80 | | | | | | | Photopolymerization | | |
| | (about | SR395 | FA-512AS | FA-513AS | FA-511AS | IBXA | A-TMPT | initiator | | |
| Resin | 3,500 cP, | (about 5 cP, | (about 20 cP, | (about 12 cP, | (about 12 cP, | (about 7.7 cP, | (about 110 cP, | (parts by mass) | | |
| compositions | 60° C.) | 25° C.) | 25° C.) | 25° C.) | 25° C.) | 25° C.) | 25° C.) | C-1 | C-2 | C-3 |
| Resin | 40 | 310 | 0 | 100 | 350 | 0 | 60 | 0 | 6 | 8 |
| composition | | | | | | | | | | |
| [1] | | | | | | | | | | |
| Resin | 50 | 0 | 471 | 0 | 0 | 348 | 0 | 3 | 0 | 0 |
| composition | | | | | | | | | | |
| [2] | | | | | | | | | | |

UV-3635ID80: hydrogenated polybutadiene-based urethane acrylate (The Nippon Synthetic Chemical Co., Ltd.)
SR-395: isodecyl acrylate (Sartomer)
FA-512AS: dicyclopentenyloxyethyl acrylate (Hitachi Chemical Co., Ltd.)
FA-513AS: dicyclopentanyl acrylate (Hitachi Chemical Co., Ltd.)
FA-511AS: dicyclopentenyl acrylate (Hitachi Chemical Co., Ltd.)
IBXA: isobornyl acrylate (Tokyo Chemical Industry Co., Ltd.)
A-TMPT: trimethylolpropane triacrylate (Shin-Nakamura Chemical Co., Ltd.)
C-1: Irgacure 379EG (BASF)
C-2: Irgacure 369 (BASF)
C-3: Darocure 1173 (BASF)

### Resist Compositions [1] to [6]

Resin composition [1] shown in Table 1 (100 parts by mass) was put into a glass sample bottle, and dextrin palmitate (product of Nikko Chemicals Co., Ltd.) (3 parts by mass) in powder form was added thereto as an organic gelling agent. The sample bottle was sealed and shaken, to thereby prepare resist composition [1] shown in Table 2.

The procedure of preparing resist composition [1] was repeated, except that the amounts of compounds were altered as shown in Table 2, to thereby prepare resist compositions [2] to [6] shown in Table 2.

### Resist Compositions [7] and [8]

12-Hydroxystearic acid (product of Johnson) (10 parts by mass) serving as an organic gelling agent was mixed with ethanol (34 parts by mass) serving as an organic solvent, and the mixture was heated at 100° C., to thereby form a solution of the organic gelling agent in ethanol. The thus-formed solution was mixed with resin composition [1] (100 parts by mass) at room temperature, to thereby prepare resist composition [7] shown in Table 2.

Notably, when the above-prepared solution of the organic gelling agent in ethanol was allowed to stand at room temperature for several hours, the organic gelling agent was precipitated. In contrast, after mixing of the solution with the polymerizable monomers, no precipitation of the organic gelling agent occurred in the resist composition during storage of about one week. Thus, ethanol plays a role in forming a homogeneous mixture of the organic gelling agent and the polymerizable monomer and dissolving the organic gelling agent, and also serves as a gelling inhibitor that can prevent formation of hydrogen bond between organic gelling agent molecules.

The procedure of preparing resist composition [7] was repeated, except that the type of the resin composition and the amounts of compounds were altered as shown in Table 2, to thereby prepare resist composition [8] shown in Table 2.

### Comparative Resist Compositions [1] and [2]

The procedure of preparing resist composition [1] was repeated, except that no organic gelling agent was used, to thereby prepare comparative resist compositions [1] and [2].

TABLE 2

| | | | | Org. | | | |
|---|---|---|---|---|---|---|---|
| | | | | gelling | | Heating | |
| | | | Org. | agent | Solvent | temp. | |
| | | Resin compn. | gelling | (parts | (ethanol) | in | |
| | Resist | (parts by | agent | by | (parts by | gelling | Gel |
| | compns. | mass) | type | mass) | mass) | step | strength |
| Ex. 1 | Resist | Resin | J-1 | 3 | — | 100° C. | Δ |
| | compn. | composition | | | | | |
| | [1] | [1] (100) | | | | | |
| Ex. 2 | Resist | | | 5 | | | ◯ |
| | compn. | | | | | | |
| | [2] | | | | | | |
| Ex. 3 | Resist | | | 10 | | | ◯ |
| | compn. | | | | | | |
| | [3] | | | | | | |
| Ex. 4 | Resist | | J-2 | 3 | | 80° C. | ◯ |
| | compn. | | | | | | |
| | [4] | | | | | | |
| Ex. 5 | Resist | | | 5 | | | ◯ |
| | compn. | | | | | | |
| | [5] | | | | | | |
| Ex. 6 | Resist | | | 10 | | | ◯ |
| | compn. | | | | | | |
| | [6] | | | | | | |
| Ex. 7 | Resist | | | 10 | 34 | | ◯ |
| | compn. | | | | | | |
| | [7] | | | | | | |
| Ex. 8 | Resist | Resin | | 6 | 11 | 60° C. | ◯ |
| | compn. | compn. [2] | | | | | |
| | [8] | (100) | | | | | |
| Comp. | Comp. | Resin | — | — | — | 100° C. | X |
| Ex. 1 | resist | compn. [1] | | | | | |
| | compn.[1] | (100) | | | | | |
| Comp. | Comp. | Resin | — | — | — | 100° C. | X |
| Ex. 2 | resist | compn. [2] | | | | | |
| | compn.[2] | (100) | | | | | |

J-1: dextrin palmitate (Nikko Chemicals Co., Ltd.)
J-2: 12-hydroxystearic acid (product of Johnson)

### Examples 1 to 8

Each of the resist compositions [1] to [8] shown in Table 2 was cast onto a soda glass substrate so as to attain a film thickness of about 60 μm. The composition was heated for one minute at a temperature specified in Table 2 and then cooled to room temperature (25° C.), to thereby cause gelation of the resist composition. As described above, the resist composition application method may be selected depending on the use of the resist, and is not limited to casting.

### Comparative Examples 1 and 2

The procedure of Example 1 was repeated, except that comparative resist composition [1] or [2] shown in Table 2 was used, to thereby cause gelation of the resist composition.

### <Practical Characteristic Evaluation 1>

### (1) Gelling Property

The resist composition was cooled to room temperature (25° C.), to thereby cause gelation of the resist composition. When a uniform gel was formed, the composition was evaluated with a rating “O.” When a uniform gel with low gel strength was formed concomitant with collapsing due to shock or the like, the composition was evaluated with a rating “Δ.” When no uniform gel was formed after cooling to room temperature, the composition was evaluated with a rating “X.” Table 2 shows the results. In all the cases of Examples 1 to 8, gel formation was observed, and the in-plane uniformity in film thickness was satisfactory.

In contrast, in Comparative Examples 1 and 2, where no organic gelling agent was used, no gel was formed after heating, and the composition remained low-viscosity liquid.

### (2) UV Curability 1

Each of the gels produced in Examples 1 to 8 for gelling property evaluation was exposed to UV light (20 mW/cm², 2.0 J/cm²) for curing. The thus-obtained cured product was found to have softness and no surface tack, indicating good curability.

The gels of Comparative Example 1 and 2 were cured by UV light. However, radical curing proceeded with considerable inhibition by oxygen, since the gels had low viscosity during UV exposure. Thus, considerable surface tack was observed. In addition, the gels were difficult to handle due to low liquid viscosity, and, during conveyance of a substrate onto which the resist composition had been applied to the UV exposure apparatus, the resist composition undesirably stained the apparatus.

### (3) UV Curability 2

The resist composition of Example 7 was applied onto a silicon substrate having a thermal oxide film (SiO₂ film thickness: 2,000 nm) through spin-coating for 60 seconds at a rotation rate of 100 rpm. During spin coating, ethanol in the resist composition was evaporated, whereby gel of the coating film was formed after spin coating. Subsequently, the gel of the resist composition was baked at 60° C. for 5 seconds to thereby thermally melt the gelled coating film, so as to attain a uniform film thickness. Further, the uniform film was exposed to UV light of 100 mJ by the mediation of a mask aligner (model MA-6, SUSS MicroTec), to thereby perform patternwise curing.

### (4) Alkali Developability

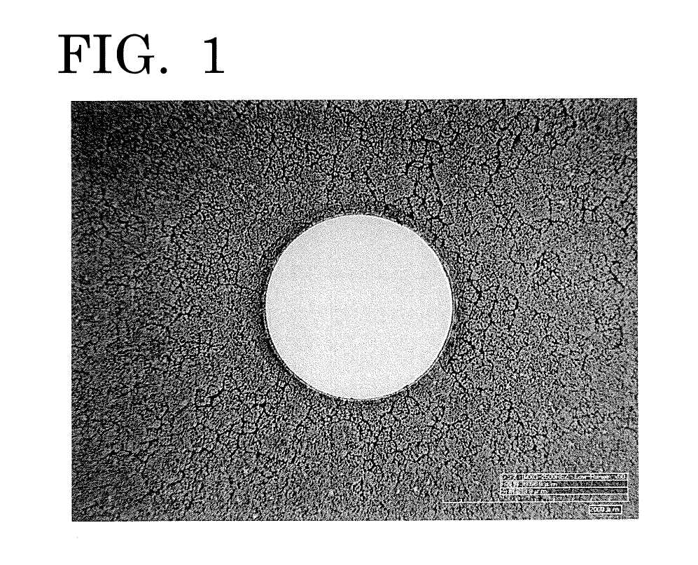

The substrate produced in “(3) UV curability 2” above was immersed in 1% aqueous potassium hydroxide for 1 minute, to thereby remove the unexposed portion. Thus, a circular pattern having a film thickness of about 45 μm and a diameter of about 2 mm was produced. FIG. 1 shows a microscopic image thereof. The unexposed portion in the circular pattern was completely removed, and no residue was observed therein, indicating excellent alkali developability.

As described above, the resist pattern formation method of the invention comprises a step of preparing a resist pattern forming composition containing at least a polymerizable monomer that is liquid at room temperature, an organic gelling agent, and a photopolymerization initiator; a step of applying, onto a substrate, the prepared resist pattern forming composition, to thereby form a coating film; a step of forming a gel with the organic gelling agent present in the coating film; and a step of patterning the coating film which has been gelled by the organic gelling agent. As a result, the composition has low viscosity, while the composition maintains high film-forming component concentration, and a thick coating film can be formed on the substrate. In addition, the resist pattern formation method of the invention can prevent undesired flow of the coating film applied onto the substrate. Thus, through employment of the resist pattern formation method, excellent handling performance can be attained. For example, a thick coating film having excellent in-plane uniformity can be maintained during conveyance thereof after application.

### <Practical Characteristic Evaluation 2>

In one use, the resist film is subjected to etching with hydrofluoric acid. The performance of the resist film in such use was evaluated.

The SiO₂ substrate provided with a resist pattern produced in “(4) Alkali developability” above was immersed in an aqueous acid mixture (i.e., 9% HF and 10% HCl, at 25° C.) (hereinafter may be referred to as an etchant). The substrate was etched for 5 minutes by swaying it by hand. Then, the substrate was washed with water, and the resist pattern was peeled from the substrate.

The inside of the circular pattern where no resist film remained underwent etching of SiO₂. In contrast, no SiO₂ etching was observed in the portion outside the circular pattern, which was protected by the resist film. Therefore, the resist composition of the present invention was found to be applicable to formation of a resist film which is employed in etching of a glass substrate or a substrate having an insulating film such as SiO₂ or SiN.

1-8. (canceled)

9. A resist pattern formation method, employing a resist pattern forming composition which comprises at least a polymerizable monomer that is liquid at room temperature, an organic gelling agent, and a photopolymerization initiator,
characterized in that the method comprises:
a step of preparing the resist pattern forming composition;
a step of applying, onto a substrate, the prepared resist pattern forming composition, to thereby form a coating film;
a step of forming a gel with the organic gelling agent present in the coating film; and
a step of patterning the coating film which has been gelled by the organic gelling agent.

10. A resist pattern formation method according to claim 9, wherein, in the gelling step, the organic gelling agent is heated at 40 to 160° C.

11. A resist pattern formation method according to claim 9, wherein the organic gelling agent is in a granular form.

12. A resist pattern formation method according to claim 9, wherein the resist pattern forming composition contains an organic solvent for dissolving the organic gelling agent.

13. A resist pattern formation method according to claim 9, wherein the resist pattern forming composition contains an emulsifier.

14. A resist pattern formation method according to claim 9, wherein, in the patterning step, the coating film formed on the substrate is cured via exposure to UV light, and then the uncured portion of the coating film on the substrate is removed with an alkaline developer.

15. A resist pattern formation method according to claim 10, wherein, in the patterning step, the coating film formed on the substrate is cured via exposure to UV light, and then the uncured portion of the coating film on the substrate is removed with an alkaline developer.

16. A resist pattern formation method according to claim 11, wherein, in the patterning step, the coating film formed on the substrate is cured via exposure to UV light, and then the uncured portion of the coating film on the substrate is removed with an alkaline developer.

17. A resist pattern formation method according to claim 12, wherein, in the patterning step, the coating film formed on the substrate is cured via exposure to UV light, and then the uncured portion of the coating film on the substrate is removed with an alkaline developer.

18. A resist pattern formation method according to claim 13, wherein, in the patterning step, the coating film formed on the substrate is cured via exposure to UV light, and then the uncured portion of the coating film on the substrate is removed with an alkaline developer.

19. A resist pattern forming composition, wherein the composition comprises at least a polymerizable monomer, an organic gelling agent, and a photopolymerization initiator, and the polymerizable monomer is liquid at room temperature.

20. A resist pattern forming composition according to claim 19, wherein the organic gelling agent is at least one of dextrin palmitate and 12-hydroxystearic acid.
